(19) United States
(12) Patent Application Publication
(10) Pub. No.: US 2026/0324029 A1
(43) Pub. Date: Oct. 15, 2026

(54) HETEROSTRUCTURES WITH FERROELECTRIC III-NITRIDE LAYER ON METAL

(71) Applicant: The Regents of the University of Michigan, Ann Arbor, MI (US)

(72) Inventors: Ping Wang, Ann Arbor, MI (US); Ding Wang, Ann Arbor, MI (US); Zetian Mi, Ann Arbor, MI (US)

(21) Appl. No.: 19/113,755

(22) PCT Filed: Sep. 20, 2023
(86) PCT No.: PCT/US2023/033254

§ 371 Date: Mar. 20, 2025

Related U.S. Application Data
(60) Provisional application No. 63/408,341, filed on Sep. 20, 2022.

(51) Int. Cl. H10D 62/85; H10B 51/30; H10D 1/00; H10D 1/40; H10D 62/40; H10D 62/852

(52) U.S. Cl. CPC H10D 62/8503; H10D 1/025; H10D 1/40; H10D 62/405; H10D 62/852; H10B 51/30

(57) ABSTRACT

In accordance with an aspect of the disclosure, a method of forming a heterostructure includes providing a metal layer of the heterostructure, the metal layer being supported by a substrate, implementing a surface treatment procedure to remove oxide from a surface of the metal layer, and, after implementing the surface treatment procedure, implementing a non-sputtered, epitaxial growth procedure to form a single-crystalline semiconductor layer of the heterostructure, the single-crystalline semiconductor layer being supported by, and in contact with, the metal layer. The single-crystalline semiconductor layer includes an alloy of a Ill-nitride material. The non-sputtered, epitaxial growth procedure is configured to incorporate a group IIIB element into the alloy of the Ill-nitride material.

### CROSS-REFERENCE TO RELATED APPLICATION

This application claims the benefit of U.S. provisional application entitled “Heterostructures with Ferroelectric III-Nitride Layer on Metal,” filed Sep. 20, 2022, and assigned Ser. No. 63/408,341, the entire disclosure of which is hereby expressly incorporated by reference.

### STATEMENT REGARDING FEDERALLY SPONSORED RESEARCH OR DEVELOPMENT

This invention was made with government support under Contracts Nos. HR0011-22-2-0024 and HR0011-22-C-0087 awarded by the U.S. Department of Defense, Defense Advanced Research Projects Agency. The government has certain rights in the invention.

### BACKGROUND OF THE DISCLOSURE

### Field of the Disclosure

The disclosure relates generally to Group III-nitride materials.

### Brief Description of Related Technology

III-nitride (III-N) semiconductors exhibit wide and tunable direct bandgaps, large breakdown strength, high electron mobility, high electron saturation drift velocity, high thermal and chemical stability, and high radiation resistance, and have emerged as the enabling technology for a broad range of applications, from solid state lighting, radio-frequency (RF) and power electronics and to quantum information, renewable energy, as well as the emerging edge computing and artificial neuro networks. Due to the absence of spatial inversion symmetry in the wurtzite (wz) crystal structure of III-N semiconductors, a large spontaneous polarization nature is exhibited, which plays a useful role in reconfiguring the interface mobile charges to form two-dimensional electron/hole gases (2DEG/2DHG) and improving the quantum efficiency of light emitting diodes (LEDs).

Recently, ferroelectricity has been demonstrated in both sputtering deposited Sc-III-N and epitaxially grown Sc-III-N using molecular beam epitaxy (MBE). In such cases, the intrinsic spontaneous polarization of the nitride semiconductors can be reconfigured by an external electric field, thereby supporting applications in memories, transistors, resonators, filters, and other devices.

### SUMMARY OF THE DISCLOSURE

In accordance with one aspect of the disclosure, a heterostructure includes a metal layer and a single-crystalline semiconductor layer supported by the metal layer. The single-crystalline semiconductor layer includes an alloy of a III-nitride material. The alloy includes a Group IIIB element. The single-crystalline semiconductor layer is in contact with the metal layer.

In accordance with another aspect of the disclosure, a heterostructure includes a metal layer and a single-crystalline semiconductor layer supported by the metal layer. The single-crystalline semiconductor layer includes an alloy of aluminum nitride. The alloy includes scandium. The metal layer includes molybdenum. The single-crystalline semiconductor layer is in contact with the metal layer.

In accordance with still yet another aspect of the disclosure, a method of forming a heterostructure includes providing a metal layer of the heterostructure, the metal layer being supported by a substrate, implementing a surface treatment procedure to remove oxide from a surface of the metal layer, and, after implementing the surface treatment procedure, implementing a non-sputtered, epitaxial growth procedure to form a single-crystalline semiconductor layer of the heterostructure, the single-crystalline semiconductor layer being supported by, and in contact with, the metal layer. The single-crystalline semiconductor layer includes an alloy of a III-nitride material. The non-sputtered, epitaxial growth procedure is configured to incorporate a group IIIB element into the alloy of the III-nitride material.

In connection with any one of the aforementioned aspects, the devices and/or methods described herein may alternatively or additionally include or involve any combination of one or more of the following aspects or features. The single-crystalline semiconductor layer is ferroelectric. The single-crystalline semiconductor layer has a wurtzite structure. A (0001) plane of the wurtzite structure is in contact the metal layer. A surface of the metal layer in contact with the single-crystalline semiconductor layer matches an atomic arrangement of the (0001) plane of the wurtzite structure. A surface of the metal layer is oriented in the (011) plane. The metal layer includes molybdenum. A surface of the metal layer is oriented in the (111) plane. The metal layer includes aluminum. The Group IIIB element is scandium. The alloy of the III-nitride material includes AIN. The metal layer is a first metal layer. The heterostructure further includes a second metal layer in contact with the single-crystalline semiconductor layer. The single-crystalline semiconductor layer is disposed between the first metal layer and the second metal layer. The heterostructure further includes a III-nitride semiconductor layer supported by, and in contact with, the single-crystalline semiconductor layer. A device includes a heterostructure as disclosed herein, in which the device further includes an electrode layer in contact with the III-nitride semiconductor layer, the single-crystalline semiconductor layer is ferroelectric, and the metal layer is configured as a further electrode such that the device is configured as a memristor. A device includes a heterostructure as disclosed herein, in which the device further includes a substrate, the substrate supporting the heterostructure. The single-crystalline semiconductor layer is ferroelectric. The metal layer is a first metal layer. The heterostructure further includes a second metal layer in contact with the single-crystalline semiconductor layer. The single-crystalline semiconductor layer is disposed between the first metal layer and the second metal layer. Implementing the surface treatment procedure includes annealing the metal layer in a vacuum. The non-sputtered, epitaxial growth procedure is implemented under a nitrogen-rich condition. The method further includes depositing a further metal layer on the single-crystalline semiconductor layer such that the further metal layer is in contact with the single-crystalline semiconductor layer. The method further includes removing the substrate such that the heterostructure is freestanding. The method further includes annealing the single-crystalline semiconductor layer.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts schematic representations and graphical plots of example epitaxial growth of single-crystalline ScAlN on Mo, including (a) an atomic schematic illustration of the epitaxial relationship between wz-ScAlN and bcc-Mo, in which “1”, “2”, and “3” represent three types of Mo domains with 60° in-plane rotation, but sharing the same epitaxial registry with wz-ScAlN, (b) a schematic illustration of ScAlN grown on a Mo template, (c, d) XRD 2θ-Ω scans and φ scans for Mo template (green, lower curve) and ScAlN grown on Mo template (pink, upper curve), and (e) EBSD maps for high-temperature annealed Mo template (lower panel) and ScAlN grown on Mo template (upper panel), in which the rectangles and hexagons in (d, e) indicate the corresponding in-plane orientation relationship between Mo domains and ScAlN, and the Mo electrode layer has three types of (011) domains with 60° in-plane rotation, whereas ScAlN shows uniform (0001) orientation without in-plane rotation.

FIG. 2 depicts imagery and graphical plots of microstructure analysis of example single-crystalline ScAlN on Mo, including (a) a cross-sectional HAADF-STEM image for ScAlN grown on a Mo template, (b, c) nano-beam electron diffraction patterns for Mo along the [100] zone-axis and ScAlN along the [112̅0] zone-axis acquired from the green and pink spots labeled in (a) using the same e-beam azimuth, showing a clear bcc and wz crystal structure, respectively, (d) a SAED pattern recorded from the ScAlN/Mo interface, demonstrating a clear (0001)[112̅0]_{ScAlN}∥(011)[100]_{Mo} epitaxial relationship, (e, f) elemental EDS maps and profile plots along the ScAlN/Mo growth direction, exhibiting a uniform Sc incorporation and a few nanometers native oxide layer near the ScAlN surface, in which curves in (f) show a quantitative trend for the distribution of Sc/Al and a qualitative trend of the distribution of nitrogen/oxygen.

FIG. 3 depicts graphical plots of the ferroelectricity of example ScAlN layers grown on Mo, including (a) P-E and J-E loops measured at 10 kHz, (b) electric field dependent remnant polarization recorded from standard PUND measurements (0.1 ms in pulse width), showing clear saturation in both branches, (c, d) retention and endurance tests for ferroelectric ScAlN grown on Mo, exhibiting a high stability and reliability after electrical poling and cycling, in which square pulses with a voltage amplitude of ±65 V and a pulse width of 0.1 ms were applied for both retention and endurance tests, (e, f) unipolar (#1, the first scan) and bipolar (#2, the second scan) C-V measurements (with a small signal voltage of AC=100 mV at 1 MHz) on two pristine ScAlN capacitors to visualize the as-grown polarization state, in which sweeping directions are labeled with arrows.

FIG. 4 depicts schematic representations and graphical plots of a ferroelectric GaN/ScAlN heterostructure memristor for synaptic emulation in accordance with one example, including (a) a schematic illustration of a pre-neuron and a post-neuron connected by a synapse, along with a resistive ferroelectric GaN/ScAlN heterostructure on Mo of the memristor, (b, c) schematic illustrations of band diagram modulation by ferroelectric polarization switching in the GaN/ScAlN heterostructure, in which, if the ScAlN polarization points downward as in part (b), electrons in the n-GaN deplete from the GaN/ScAlN interface and, therefore, positively charged immobile donor ions screen the bound polarization charges, leading to the formation of a higher electron transport barrier (Φ_{down}), and in which, when ScAlN polarization is reversed as in part (c), electrons accumulate at the GaN/ScAlN interface, reducing the electron transport barrier (Φᵤₚ), (d) an I-V loop measured from the GaN/ScAlN memristor (blue, upper curve) and a ScAlN capacitor (gray, lower curve) with a step size of 0.1 V, in which the sweeping direction is labeled with arrows (+Δ0Δ-Δ0Δ+), (e) a graphical plot of ON/OFF current measured in a small voltage range without destructing the ScAlN polarization, in which the ScAlN polarization was preset to ON and OFF state, respectively, and, in which, with a read voltage of +10 V (dashed line), the corresponding ON/OFF ratio is about 40, (f) a graphical plot of conductance of the GaN/ScAlN memristor as a function of voltage pulses (20 ms in pulse width), (g) a graphical plot of the evolution of the GaN/ScAlN memristor conductance as a function of identical pulse numbers, showing potentiation and depression characteristics, (h) graphical plots of voltage waveforms used to emulate the pre-neuron (red) and post-neuron (blue) voltage spikes with a total length of 10 ms, and (i) graphical plots of variations of synaptic strength (ΔI) of an ferroelectric GaN/ScAlN memristor based artificial synapse with respect to the delay time (Δt), showing a clear biological STDP behavior.

FIG. 5 depicts a cross-sectional, schematic view of a device having a heterostructure with an epitaxially grown single-crystalline III-nitride alloy layer in accordance with one example.

FIG. 6 is a flow diagram of a method of fabricating a heterostructure having an epitaxially grown single-crystalline III-nitride alloy layer in accordance with one example.

FIG. 7 depicts a cross-sectional, schematic view of a memory cell having a heterostructure with an epitaxially grown single-crystalline III-nitride alloy layer in accordance with one example.

FIG. 8 depicts a cross-sectional, schematic view of another transistor device having a heterostructure with an epitaxially grown single-crystalline III-nitride alloy layer in accordance with one example.

FIG. 9 depicts a cross-sectional, schematic view of a memory device having a heterostructure with an epitaxially grown single-crystalline III-nitride alloy layer in accordance with one example.

FIG. 10 depicts a cross-sectional, schematic view of a device having a freestanding heterostructure with an epitaxially grown single-crystalline III-nitride alloy layer in accordance with one example.

FIG. 11 depicts example ScAlN films grown on Mo before and after annealing, including (a) images showing surface morphology, and graphical plots of (b) dielectric properties, (c) leakage current, and (d) a butter-fly shaped C-V loop indicating ferroelectric switching in the epitaxial ScAlN films, in which the ScAlN film without annealing exhibited a low breakdown voltage and an unmeasurable butterfly shaped C-V loop.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Heterostructures with a III-nitride alloy layer on a metal layer are described. The III-nitride alloy layer is supported by, and in contact with, the metal layer. The III-nitride alloy layer may be single-crystalline or monocrystalline despite a polycrystalline nature of the metal layer. A surface of the metal layer may be oriented in a plane that matches the atomic arrangement of a wurtzite (0001) plane of the single-crystalline III-nitride alloy layer. In some cases, the III-nitride alloy layer is ferroelectric, such as a ferroelectric ScAlN layer. In some cases, the metal layer is composed of, or otherwise includes, molybdenum (Mo). The III-nitride alloy layer supported by the metal layer may be used in a variety of heterostructure arrangements and corresponding devices, including, for instance, capacitors and memristors (e.g., synaptic memristors), examples of which are described below. Methods for fabricating such heterostructures and devices are also described.

The disclosed heterostructures, devices, and methods may integrate ferroelectric ScAlN and other III-nitride alloys with various metal materials. For instance, the metal materials may include metals compatible with complementary metal-oxide semiconductor (CMOS) circuits and fabrication processes. Such integration will apply the advantages of ferroelectric III-nitride materials (e.g., ScAlN) to enable applications from single devices to systems and even hybrid integrated circuits. For instance, making ferroelectric III-nitride materials compatible with CMOS and other technologies involves achieving single-crystalline ferroelectric ScAlN heterostructures on metal electrodes. Yet sputter deposited films are generally polycrystalline with very limited material quality.

The realization of fully epitaxial, single-crystalline ferroelectric III-N, e.g., ScAlN, on metal electrodes provides unique opportunities in bandgap/polarization engineering, interface/defects/doping control, thermal management, and high yield mass production. To date, however, the achievement of single-crystalline III-N semiconductors on metal has remained elusive, due to the severe lattice misalignment, highly reactive metallic surface, and lack of highly orientated metal substrate/template.

Among the commonly used CMOS compatible metals, the high melting point (about 2160° C.), low thermal expansion coefficient (5×10⁻⁶° C.⁻¹ at 20° C.), and low electrical resistivity (5×10⁻⁸ Ω·m) of molybdenum (Mo) make it a useful metal to withstand thermal budgets encountered in CMOS fabrication process. Additionally, Mo has a low acoustic attenuation due to the high acoustic velocity, and can also be easily wet etched. As such, Mo may be used as a bottom electrode for high frequency acoustic filters and resonators. Therefore, epitaxially grown III-N heterostructures on Mo may be used to achieve CMOS compatible ferroelectric nitrides and fully nitride-based complementary circuits, as well as a new class of integrable, ultralow loss, and ultrahigh frequency acoustoelectronic devices. This combination of III-N heterostructures on Mo also supports the integration of nonvolatile ferroelectric memristors (e.g., ScAlN memristors) with processors, which may be used, for instance, as a building block for rapid data transmission and analysis in artificial neural networks.

Described herein are examples of single-crystalline ferroelectric ScAlN on CMOS compatible Mo metal layers, including examples configured as synaptic memristors. The epitaxial relationship between single-crystalline wz-ScAlN and the underlying body-centered cubic (bcc) Mo are unambiguously determined and characterized by a number of techniques. Stable, robust, and wake-up-free ferroelectricity was measured in the examples—for the first time, in ScAlN epitaxially grown on metal. The resistive switching behavior in ferroelectric GaN/ScAlN memristors grown on Mo and its application in emulating the biological neuron-like spike-time-dependent plasticity (STDP) in artificial synapse is also described. Although described in connection with the above-referenced examples, the growth of single-crystalline ferroelectric nitride semiconductors on metals (e.g., CMOS compatible metals, such as Mo) of the disclosed devices and methods may be useful in a wide variety of next-generation electronic, acoustic, photonic, and quantum devices and systems.

Although described in connection with examples of epitaxially grown ScAlN layers, the disclosed heterostructures, devices and methods may be applied to a wide variety of III-nitride alloys. The disclosed heterostructures, devices and methods may thus include or involve the incorporation of scandium into other III-nitride wurtzite structures. For instance, the disclosed heterostructures, devices and methods may include or involve one or more epitaxially grown ScAlGaN layers, ScAlInN layers, ScGaN layers, or ScInN layers. The configuration, construction, fabrication, and other characteristics of the heterostructures may also vary from the examples described. For instance, the heterostructures may include any number of epitaxially grown layers of ferroelectric and non-ferroelectric nature.

The disclosed heterostructures, devices and methods are also not limited to III-nitride alloys including scandium. For instance, the III-nitride alloys may include additional or alternative group IIIB elements, such as yttrium (Y) and lanthanum (La).

Although some aspects of the disclosed methods are described in connection with MBE growth procedures, additional or alternative non-sputtered epitaxial growth procedures may be used. For instance, metal-organic chemical vapor deposition (MOCVD) and hydride vapor phase epitaxy (HVPE) procedures may be used. Still other procedures may be used, including, for instance, pulsed laser deposition (PLD) procedures and atomic layer deposition (ALD) procedures.

Although described in connection with examples in which the III-nitride alloy is grown on a Mo layer, the disclosed heterostructures, devices and methods are not limited to growth on Mo layers. A variety of metals may be used, including, for instance, Al, Pt, Ti, Fe, Cu, and Ni. Although described in connection with polycrystalline metal layers, the disclosed heterostructures, devices and methods may alternatively or additionally include or use single-crystalline or monocrystalline metal layers.

III-N semiconductors with wz-phase (space group P6₃mc) lattices have the strongest polarization along the c-axis direction. Therefore, growing along <0001> direction maximizes the remnant polarization in ferroelectric nitrides. However, growth along alternative or additional directions may be implemented in other cases.

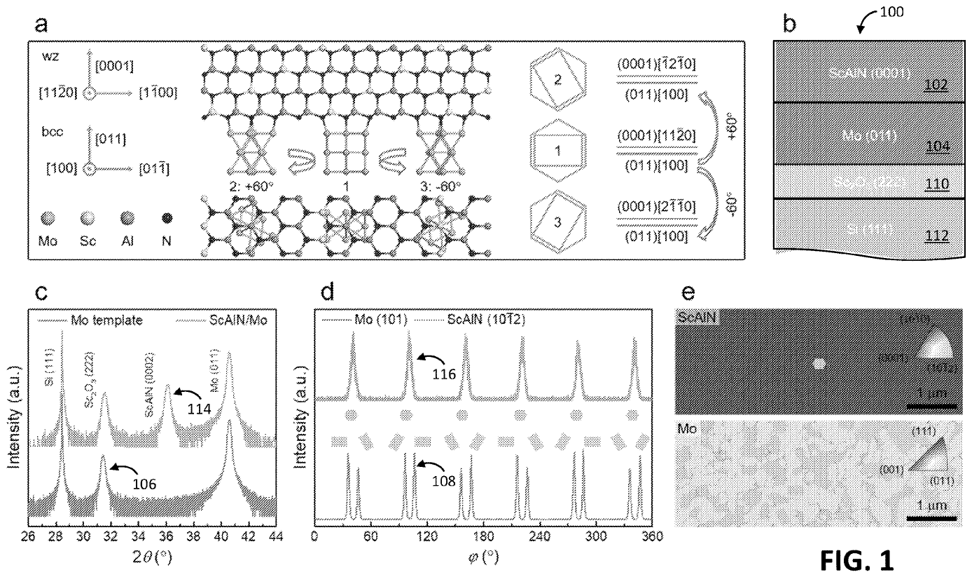

FIG. 1, part a, displays the atomic structure of crystalline Mo with bcc-phase (space group Im3̅m). Among the {100}, {011}, and {111} planes in bcc-phase metals, the {011} plane is a useful candidate for epitaxial growth of nitrides along <0001> direction, due to the compatible in-plane symmetry, low surface energy, and low reactivity. Additionally, the {011} plane is the most readily available orientation in either epitaxially grown or sputtering deposited Mo electrodes or templates. Therefore, in the examples described below, the III-nitride layers were grown on Mo(011) templates. A GENxplor MBE system was used in each case.

FIG. 1, part b, shows a structure 100 having a ScAlN layer 102 grown on a Mo template 104 in accordance with one example. However, due to the lack of a proper substrate, preparation of a single-crystalline Mo film on a foreign substrate is difficult. For the Mo template 104, a sharp Mo(011) peak was observed in the X-ray diffraction (XRD) 2θ-ω scan (see FIG. 1, part c, lower curve 106), but the φ scan (2θ=40.6°, χ=60°, FIG. 1, part d, lower curve 108) showed a six-fold symmetry with two azimuthal peaks separated by an in-plane tilt angle of 10.6°, which is inconsistent with the expected twofold symmetry. These phenomena indicate that the Mo(011) template 104 is polycrystalline and includes triplet domains with 60° in-plane rotation, labeled as rotated rectangles in FIG. 1, part d. Electron backscatter diffraction (EBSD) map showed that these domains are randomly distributed across the Mo layer 104. Epitaxial growth of a single-crystalline structure on this type of template, substrate, or other underlying layer is challenging. However, the optimum adsorption sites of atoms on (011)_{bcc} plane result in a [112̅0]_{wz}∥[100]_{bcc} (Pitsch-Schrader type) in-plane alignment. In such case, the in-plane rectangular lattices of the 60°-rotated triplet Mo(011) domains match the same in-plane hexagonal lattice of (0001)_{wz} with an epitaxial registry of (0001)[112̅0]_{wz}∥(011)[100]_{bcc} (see FIG. 1, part a). Meanwhile, the in-plane lattice mismatch between Mo and Sc_{0.2}Al_{0.8}N (AlN) is only 2% (1.1%) under this alignment. As a result, epitaxial growth of single-crystalline wz-phase III-N may be grown on bcc-phase metals, such as Mo, Fe, etc. The schematic of FIG. 1, part b, shows a Sc₂O₃ layer 110 that was included to support the characterization of the epitaxial relationship between a Si substrate 112 and the Mo metal layer 506, and accordingly may not be present in examples of the disclosed heterostructures and devices.

To realize the above-described epitaxial relationship, pre-annealing at 900° C. in the MBE growth chamber was performed to remove the native oxide (e.g., MoO₃) and obtain a fresh, clean, and atomically smooth Mo(011) surface. After ScAlN growth, the characteristic peak at about 36° in the XRD 2θ-ω scan (FIG. 1, part c, upper curve 114) and the presence of six azimuthal peaks at an interval of exactly 60° in the φ scan (2θ=49.3°, χ=43°) (see FIG. 1 part d, upper curve 116) confirmed a single-crystalline wz-phase for the ScAlN epilayer 102 without in-plane rotation and cubic phase. Furthermore, in the φ scans, each ScAlN peak is located exactly at the center of the two peaks from the Mo template 104, thereby validating the predicted (0001)[112̅0]_{ScAlN}∥(011)[100]_{Mo} epitaxial relationship. The triplet domain feature for the high-temperature annealed Mo template 104 and the uniform (0001) orientation for ScAlN epilayer 102 were further confirmed by the EBSD maps, shown in FIG. 1, part e.

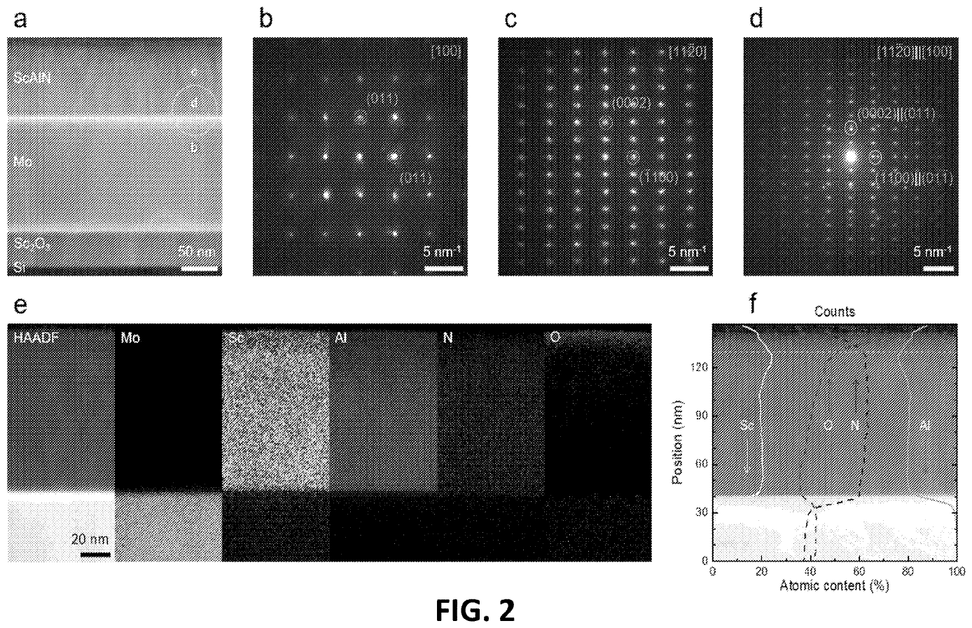

The microstructure for the ScAlN/Mo heterostructure 100 was further characterized using scanning transmission electron microscopy (STEM). FIG. 2, part a, shows the cross-sectional high-angle annular dark field (HAADF) STEM image for an example ScAlN layer grown on an Mo template. The nano-beam electron diffraction (NBED) patterns recorded from a Mo domain along the [100] zone-axis and the ScAlN layer along the [112̅0] zone-axis are presented in FIG. 2, parts b and c, respectively. For the Mo layer, except for the diffraction pattern from the [100] zone-axis, diffraction patterns close to the <111> zone-axis with an off-axis angle of ±5.3° were also observed with the same e-beam azimuth, originating from the 60°-rotated domains. However, only one kind of diffraction pattern was observed across the ScAlN epilayer, confirming that the ScAlN epilayer has a single wz-phase crystal structure. The predicted lattice alignment between wz-ScAlN and bcc-Mo was further confirmed using a selective area electron diffraction (SAED) pattern recorded from the ScAlN/Mo interface (FIG. 2, part d). This is the first demonstration of a single-crystalline wurtzite nitride semiconductor layer on a polycrystalline metal (e.g., Mo(011)) template, known to the inventors.

FIG. 2, part e, presents the energy dispersive X-ray spectroscopy (EDS) maps for the ScAlN/Mo heterostructure. The corresponding elements profile is shown in FIG. 2, part f. Overall, Sc and Al have uniform incorporation along the growth direction with an Sc content of about 0.2. However, a significant reduction of the nitrogen (N) signal, accompanied by increasing oxygen (O) signal, was observed near the surface, suggesting a native oxide ((ScAl)Oₓ) layer with a thickness of a few nanometers formed on the top surface when exposed to air, which is mainly due to the large oxygen affinity of Sc and Al. This native oxide layer may be used as either a dielectric layer or barrier layer in ScAlN-based electronic and memory devices. In other cases, the native oxide layer may be removed. The formation of the native oxide layer may also be avoided by not exposing the heterostructure to air (e.g., before subsequent processing). For example, a semiconductor may be grown or otherwise deposited on top of the ScAlN layer in situ (e.g., in the MBE chamber). Alternatively or additionally, a metal or other layer may be deposited on the ScAlN layer after the growth procedure.

Electrical characterization was performed to determine the ferroelectric polarization switching as well as the initial polarization state of the ScAlN/Mo heterostructure. Polarization/displacement current density variations with electric field (P-E/J-E), positive up and negative down (PUND), retention, endurance, and capacitance-voltage (C-V) measurements were performed on capacitors having a Ti/Au/Ti/ScAlN/Mo (metal-ferroelectric-metal, or MFM) arrangement. In this example, the diameter of the top circular Ti/Au/Ti electrodes is 50 μm, and all electrical measurements were done by applying voltage from the top electrode. The pulse sequences used for PUND and retention measurements is described in P. Wang et al., Appl. Phys. Lett. 2021, 118, 223504, the entire disclosure of which is hereby incorporated by reference.

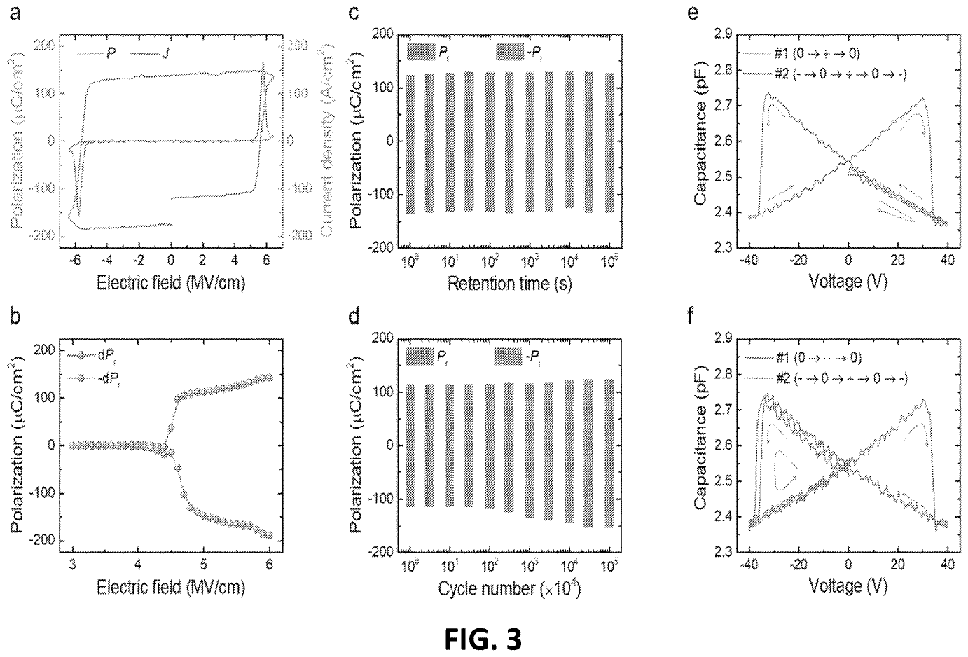

FIG. 3, part a, shows the P-E loop and the corresponding J-E loop (without leakage subtraction) measured from the MFM capacitor. The saturated polarization and characteristic displacement current peaks demonstrate clear ferroelectric polarization switching for the epitaxially grown ScAlN on Mo. The MFM capacitor exhibits a symmetric switching behavior with almost the same coercive field (±5.8 MV/cm) on both positive and negative branches. Considering the presence of a thin native oxide layer on the ScAlN surface, the coercive field may be slightly overestimated.

FIG. 3, part b, illustrates the remnant polarization recorded from the electric field dependent PUND measurements, showing a saturated remnant polarization of about 120 μC/cm² in the positive branch, which is comparable to those obtained for ScAlN/GaN heterostructures with a similar Sc content. The slightly overestimated remnant polarization in the negative branch is due to the contribution of leakage at higher electric field.

The stability and reliability of the ScAlN ferroelectric layer was further evaluated using retention and endurance tests, in which the remnant polarization for both directions shows negligible fluctuation in 10⁵ s after electrical poling (FIG. 3, part c), and exhibited no apparent fatigue behavior over 10⁵ switching cycles (FIG. 3, part d). These results are in line with what has been observed in ScAlN grown on GaN with a similar Sc content, suggesting robust ferroelectricity for the epitaxially grown ScAlN on Mo.

The as-grown lattice-polarity or polarization states for III-N epitaxially grown on a metallic template or substrate has been rarely reported, due to the existence of misorientation and mixed phases. To date, most of the sputtering deposited ScAlN on metal electrodes usually favors an N-polar lattice. Therefore, exploring the polarization states of epitaxially grown, single crystalline ScAlN on Mo is of great interest, and is also of great utility for future fully epitaxial heterogeneous integration with conventional III-N technology. In ferroelectric nitrides, the as-grown lattice-polarity can be determined by unipolar electrical measurements, such as C-V and J-E measurements. Usually, a sudden drop of capacitance can be observed when the ferroelectric polarization switching occurs, resulting in a butterfly shaped C-V loop in the bipolar measurements for a ferroelectric material.

FIG. 3, part e, depicts the C-V curves of the first unipolar (#1) and the second bipolar (#2) scans recorded on a pristine capacitor. Similar measurements on a separate capacitor were also performed and are shown in FIG. 3, part f. The dissipation factor (tan δ) for these C-V measurements was less than 0.1 from −40 to +40 V, ensuring the precision of the capacitance values. In the first unipolar scan (#1) for a fresh capacitor, the capacitance overlaps exactly in a positive sweep (FIG. 3, part e), while a sudden drop of capacitance is clearly observed in a negative sweep (FIG. 3, part f). These phenomena indicate that the polarization of the example ScAlN layer is only switched by applying a negative voltage, i.e., it has a uniform downward polarized state with a metal (M)-polar lattice. This has been also confirmed by unipolar J-E measurements. In the following bipolar scan (#2), identical butterfly shaped C-V loops were observed in these two devices, confirming the bipolar switchable polarization for the example ScAlN layer.

The negligible capacitance fluctuation in unipolar and bipolar sweeps indicates a wake-up-free nature for the example ScAlN layer. For comparison, it has remained challenging to achieve such wake-up-free ferroelectric by conventional sputter deposition. The realization of wake-up-free ferroelectric nitride semiconductors is useful for a wide range of applications, including ferroelectric memory, self-powered photodetector, acoustic filters and resonators, and piezoelectric energy harvesters, to name just a few.

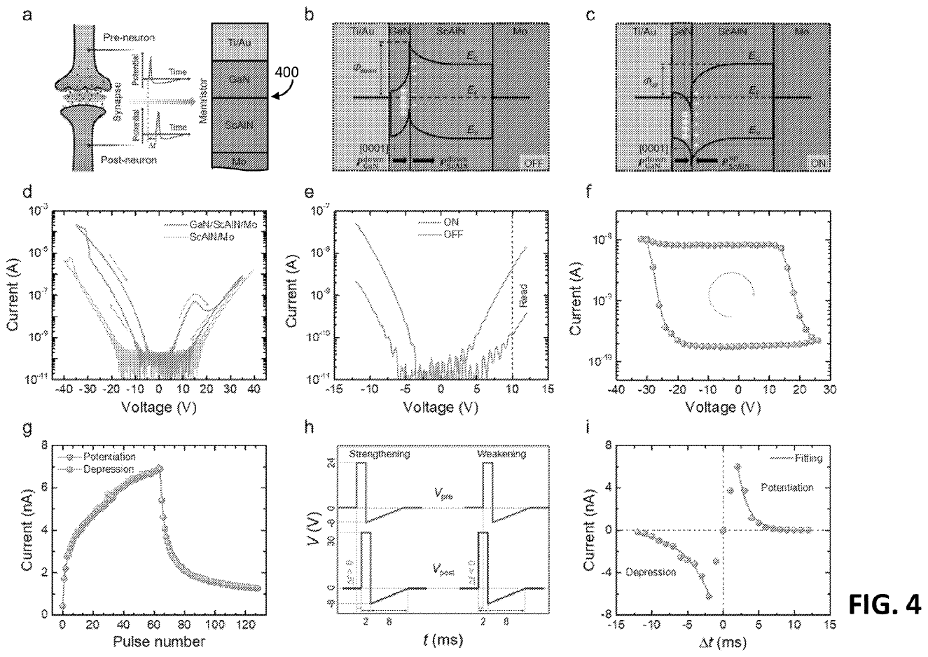

FIG. 4, part a, illustrates a resistive memristor 400 having a heterostructure with a ferroelectric layer in accordance with one example. The memristor 400 is one example of an application of ferroelectric layers (e.g., ScAlN layers) and its integration with conventional III-N layers or heterostructures on a metal template, substrate, or other underlying layer. The memristor 400 may include a substrate, such as a silicon substrate, that supports the metal layer (e.g., Mo layer) and other layers of the heterostructure. In this example, the heterostructure is a GaN/ScAlN/Mo heterostructure. The layers, composition, and other characteristics of the heterostructure may vary in other cases. For instance, in some cases, the Mo or other metal layer may also act or serve as a substrate. A growth or sacrificial substrate may thus be removed in some cases.

In the example of FIG. 4, the resistive memristor 400 is configured to emulate a biological synapse, as shown in FIG. 4, part a. The synaptic strength of a synapse, i.e., potentiation and depression, can be dynamically modified and stored by biopotentials. STDP has been proposed as a useful mechanism to describe this bioprocess. This essential biological synaptic plasticity can be emulated by using a two-terminal ferroelectric memristor with a continuously tunable resistance, which may be used as a fundamental element for an artificial neural networks.

Oxide-based ferroelectric memristors have been widely used in synaptic emulation. However, the migration and accumulation of the unavoidable oxygen vacancies at the electrode interfaces and film grain boundaries during electric field cycling always cause domain-wall pinning and gradual structural collapse, thereby limiting the endurance. Additionally, the non-polar to polar phase transition and the oxygen vacancies induced domain-wall pinning-depinning often lead to a significant wake-up effect in oxide ferroelectrics, hindering their practical applications in ferroelectric memory devices.

Compared with oxide ferroelectrics, the large remnant polarization (70-120 μC/cm²), wake-up-free, and low nitrogen vacancy formation energy nature of the epitaxially grown Sc-III-N ferroelectrics described herein are useful in scaling device size, increasing memory density, reducing power consumption, and increasing endurance. The epitaxial ferroelectric Sc-III-N memristors may thus be applied in neuromorphic computing. In comparison to previous resistive switching achieved through polarization engineering in a ferroelectric ScAlN/GaN heterostructure, in this case, the heterostructure is reversed, i.e., the GaN layer is grown on top of the ScAlN layer, e.g., to avoid the native oxide layer induced additional band diagram modification. In one example, a 20-nm-thick Si-doped n-type GaN layer (electron concentration of about 1×10¹⁸ cm⁻³) was grown on top of a 100-nm-thick ScAlN layer. The switchable polarization for the ScAlN in the example GaN/ScAlN heterostructure was confirmed by C-V measurements.

FIG. 4, parts b and c, show the band diagram of the GaN/ScAlN heterostructure, in which the ScAlN layer has a reconfigurable polarization direction. On the basis of the above lattice-polarity analysis, the GaN layer may also have a metal (M)-polar lattice, i.e., a downward polarization state. Due to the ferroelectric field effect, the barrier height (Φ) at the heterostructure interface will change significantly with the polarization reconfiguration of the ScAlN layer. The downward polarization of the ScAlN layer gives rise to negative net polarization charges at the interface, leading to the formation of a depletion region in the GaN layer and, therefore, an increased barrier height (Φ_{down}), corresponding to OFF state. The upward polarization of the ScAlN layer results in positive net polarization charges at the interface, causing an electron accumulation region at the interface and, therefore, a decreased barrier height (Φᵤₚ), corresponding to ON state. These two nonvolatile states enable the resistive switching in the disclosed GaN/ScAlN heterostructure.

The resistive switching behavior of the above-described GaN/ScAlN memory devices was characterized using quasi-static I-V measurements. FIG. 4, part d, shows the representative static I-V loops, showing clear bipolar hysteresis. Sweeping back from positive bias (ScAlN polarization downward) shows a low current state (OFF). Scanning back from negative bias (ScAlN polarization upward) exhibits a high current state (ON), agreeing well with the prediction from the band diagram. The ON and OFF current for the GaN/ScAlN heterostructure memristor has a distinct separation as compared to that for a ScAlN single layer capacitor (gray, lower curve).

FIG. 4, part e, plots the ON and OFF currents measured in a small voltage range. A stable ON/OFF ratio of about 40 is achieved with a read voltage of +10 V. The memristive effect is illustrated more clearly by reading the current at +10 V after the application of voltage pulses (pulse width 20 ms) with varying amplitudes, as shown in FIG. 4, part f. Unless stated otherwise, the same read voltage (+10 V) was used in the following measurements to minimize the bias stress effect.

In synaptic emulation, the memristor conductance may be considered as the synapse strength. Therefore, the increase (decrease) of conductance corresponds to the potentiation (depression) of the synaptic connection intensity. FIG. 4, part g, presents the continuous modulation of conductance for a GaN/ScAlN memristor programmed by 64 identical negative pulses for potentiation followed by 64 identical positive pulses for depression. The memristor conductance can be gradually regulated by applying either negative or positive voltage spikes, confirming the conductance plasticity ability. Finally, to implement STDP in the memristor, voltage waveforms shown in FIG. 4, part h, were applied to the GaN/ScAlN memristors to emulate the pre-and post-neuron activities (Vₚᵣₑ and Vₚₒₛₜ). The voltage waveform included a square voltage pulse followed by an opposite voltage with a constant slope, which was used to simulate the biological potential illustrated in FIG. 4, part a. The maximum voltage never exceeds the threshold voltage determined under the same pulse width (Vₜₕ⁺=+30 V and Vₜₕ⁻=−36 V for a pulse width of 2 ms). Therefore, a single spike cannot change the polarization in ferroelectric ScAlN, as well as the memristor resistance. However, when the pre-and post-neuron spikes arrive at the two terminals of the memristor with a time delay of Δt, their superposition produces new waveforms (Vₚᵣₑ−Vₚₒₛₜ) , which can exceed the threshold voltage transitorily.

For the synaptic potentiation (depression) emulation, a memristor was preset to OFF (ON) state, and the current difference (ΔI) after and before executing the combined waveforms was recorded. As displayed in FIG. 4, part i, for a causal relation (Δt>0), the voltage spike leads to strengthened synaptic connectivity, i.e., potentiation, as indicated by the positive ΔI. While an anti-causal relation (Δt<0) results in weakened synaptic connectivity, i.e., depression. These results suggest that the emulation of biological STDP using a single artificial synapse based on the ferroelectric GaN/ScAlN heterostructure resistive memristor can be realized, which further demonstrates the promising applications of ferroelectric III-N architectures in neural networks and neuromorphic computing.

The operating voltage may vary in other cases. For instance, the operating voltage may be significantly reduced by using a thin ferroelectric ScAlN layer.

Described above are examples of the epitaxy of single-crystalline wz-phase ferroelectric ScAlN on CMOS compatible Mo metal electrodes. A unique epitaxial relationship of (0001)[112̅0]_{wz}∥(011)[100]_{bcc} between wz-ScAlN and bcc-Mo was confirmed by using RHEED, XRD, EBSD, and STEM. The epitaxially grown ScAlN films on a Mo template or other layer exhibit stable, reliable, and wake-up-free ferroelectricity with a highly uniform M-polar as-grown lattice. The remnant polarization, coercive field, retention time, and cycling endurance are comparable with ScAlN layers grown on GaN templates. Finally, clear resistive switching has been achieved in a ferroelectric GaN/ScAlN/Mo heterostructure. Furthermore, the STDP characteristics in biological synapses have been emulated using GaN/ScAlN ferroelectric memristors.

The disclosed heterostructures may be used in other applications involving the heterogeneous integration of III-N architectures and CMOS technology. For instance, the nitride-based ferroelectrics of the disclosed heterostructures may be integrated in various other devices, systems, or applications, including a variety of advanced computing applications.

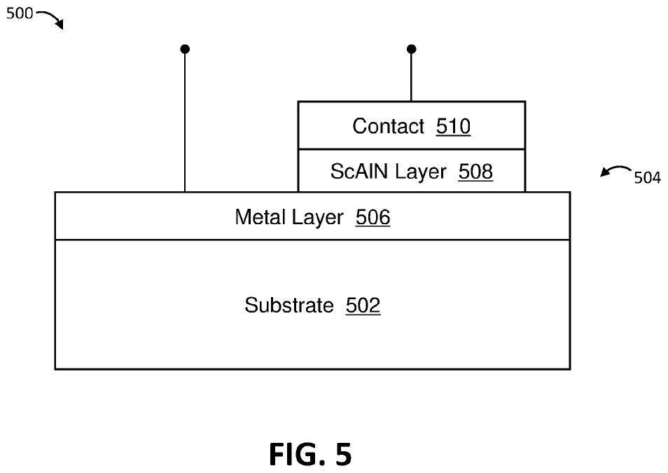

FIG. 5 depicts a device 500 having a heterostructure with a III-nitride layer on metal in accordance with one example. In this example, the device 500 is a two-terminal device. In some cases, the device 500 is configured or operated as a capacitor. The device 500 may include any number of alternative or additional layers or structures. For instance, the device 500 may be integrated with any number of other devices.

The device 500 includes a substrate 502 and a heterostructure 504 supported by the substrate 502. The substrate 502 may be composed of, or otherwise include, silicon. Additional or alternative substrate materials may be used, including, for instance, sapphire, silicon carbide, bulk GaN, bulk AlN, GaN templates, and AIN templates. The substrate 502 may be uniform or composite.

The heterostructure 504 includes a metal layer 506 and a single-crystalline semiconductor layer 508 supported by the metal layer 506. As described herein, the single-crystalline semiconductor layer 508 is composed of, or otherwise includes, an alloy of a III-nitride material, such as ScAlN. In some cases, the single-crystalline semiconductor layer 508 is ferroelectric. The single-crystalline semiconductor layer 508 may have a (0001) orientation. The orientation may vary in accordance with the epitaxial relationship between the metal layer 506 and the single-crystalline semiconductor layer 508. The metal layer 506 may be single-crystalline (or monocrystalline) or polycrystalline.

The alloy includes a Group IIIB element, such as Sc. The alloy may include one or more alternative or additional Group IIIB elements. In some cases, the III-nitride alloy is ScAlN. Alternative or additional III-nitride materials may be used, including, for instance, alloys of III-nitrides that include another group III element, such as Ga or In. Alternative or additional Group IIIB elements may be used, including, for instance, yttrium (Y) and lanthanum (La).

As shown in FIG. 5, the single-crystalline semiconductor layer 508 is in contact with the metal layer 506. In this example, the surface of the metal layer 506 in contact with the single-crystalline semiconductor layer 508 is oxide-free. In some cases, the surface of the metal layer 506 in contact with the single-crystalline semiconductor layer is oriented in the (011) plane. The plane in contact with the semiconductor layer 508 may vary in other cases, e.g., in accordance with the composition of the metal layer 506. For instance, with each metal material, the plane that matches (e.g., best matches) the atomic arrangement of the (0001) plane of the wurtzite structure may be used. In the example of FIG. 1, although the Mo (011) surface has a rectangular atomic arrangement, the rectangular atomic arrangement matches well with the hexagonal lattice of the III-N (0001) surface. The manner in which the planes match may thus vary with other atomic arrangements. For instance, the (111) plane may be in contact with the single-crystalline semiconductor layer 508 in heterostructures having an Al, Ni, or Cu layer in contact with the semiconductor layer 508. Other metal materials having the (011) plane matching the wurtzite structure may be used, including, for instance, Fe.

The metal layer 506 may be composed of, or otherwise include, Mo. Additional or alternative metals may be used, as described above, including, for instance, Al, Ni, Cu, and Fe.

The device 500 includes one or more electrodes or contacts. In this example, the heterostructure 504 further includes a top or upper contact 510 or other electrode in contact with the III-nitride semiconductor layer 508. The contact 510 may be composed of one or more metal layers, such as Ti and Au. In this example, the underlying metal layer 506 serves as a bottom or lower electrode. Additional or alternative contacts, electrodes or other structures may be included. In one capacitor example, 50-nm-Ti/100-nm-Au/50-nm-Ti circular pads with a diameter of 50 μm were lithographically patterned on the top surface of ScAlN as the top electrodes, while the bottom Mo layer was used as the bottom electrode. In other cases, such as the memristor example described above with a GaN/ScAlN/Mo heterostructure, to isolate each device, after the deposition of Ti/Au/Ti top electrodes, any uncovered portions of the GaN layer may be etched away, e.g., using a reactive ion etching (RIE) process

In some cases, the single-crystalline semiconductor layer 508 is ferroelectric. In the example of FIG. 5, the heterostructure 504 lacks a buffer layer between the single-crystalline semiconductor layer 508 and the metal layer 506. The device 500 thus provides an example of buffer-free direct epitaxial heterointegration between single-crystalline wurtzite phase ScAlN and a metal layer.

In this case, the metal layer 506 is in contact with the substrate. Alternatively, one or more layers or structures are disposed between the metal layer 506 and the substrate 502.

In some cases, the single-crystalline semiconductor layer 508 has an atomically smooth surface. The terms “atomically smooth” may be used herein in connection with layers of a heterostructure to indicate a layer having a surface roughness (e.g., a root mean square, or RMS, roughness) less than or on the order of 1 nm. In some cases, the RMS roughness of such atomically smooth layers is less than 1% of the thickness of the layer. The surface roughness may vary in accordance with the growth conditions, parameters, and other aspects of the fabrication processes described and/or referenced herein and/or other processes.

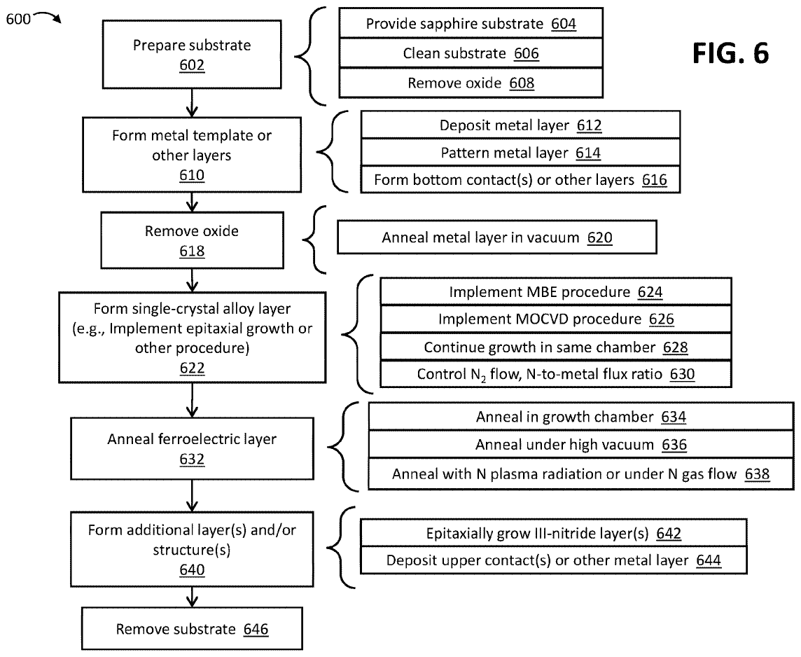

FIG. 6 depicts a method 600 of fabricating a heterostructure having a single-crystalline semiconductor layer (or wurtzite structure) of an alloy of a III-nitride material with scandium and/or another IIIB element incorporated therein in accordance with one example. As described herein, the method 600 is configured such that the III-nitride alloy layer may be grown on a metal template, substrate, or other underlying layer. The method 600 may be configured such that the wurtzite structure exhibits ferroelectric behavior. The heterostructure may form a device, or a part of a device, in which one or more layers or regions of the device exhibit the ferroelectric behavior. The method 600 may be used to fabricate the examples of devices, heterostructures, and other structures having ScAlN films or other III-nitride alloy layers described herein, and/or other devices, heterostructures or structures.

The method 600 may begin with an act 602 in which a substrate is prepared and/or otherwise provided. In some cases, the act 602 includes providing a silicon substrate in an act 604. The silicon substrate may have a (111) orientation. The substrate may be patterned or otherwise processed to configure the substrate to reduce defect formation in subsequently grown layers of the heterostructure and/or otherwise improve material quality therein. Such processing may also facilitate the formation of a different regions of the heterostructure.

Alternative or additional substrate materials may be used, including, for instance, sapphire, bulk GaN, bulk AlN, or other semiconductor material. Still other materials may be used, including, for instance, silicon carbide. In still other cases, a metal substrate may be used. For instance, the metal substrate may be composed of, or otherwise include, Al, Pt, and/or Mo.

The substrate may be cleaned in an act 606. In some cases, a native or other oxide layer may be removed from a substrate surface in an act 608. The oxide removal may include multiple steps, including, for instance, an etch step and an annealing step.

Additional or alternative processing may be implemented in other cases, including, for instance, doping or deposition procedures. The substrate thus may or may not have a uniform composition. The substrate may be a uniform or composite structure. Any number of layers or structures may be deposited on the substrate prior to the implementation of the acts described below.

The method 600 may include an act 610, in which one or more metal template or other layers are formed or otherwise provided. The metal layer is supported by the substrate. In some cases, the metal layer is in contact with the substrate. In other cases, one or more buffer or other layers or structures are disposed between the polycrystalline metal layer and the substrate.

In the example of FIG. 6, the act 610 includes an act 612 in which the metal layer(s) are deposited. A wide variety of deposition procedures may be used. In some cases, the metal layer(s) are patterned in an act 614.

The act 610 may include the deposition or other formation of one or more other metal layers or structures. For example, a bottom contact may be formed in an act 616. The act 616 may be implemented in parallel with (e.g., as part of) the act 612. The number and other characteristics of the metal layers or structures may vary in accordance with the configuration of the device (e.g., the number of terminals).

The method 600 includes an act 618 in which a surface treatment procedure is implemented to remove oxide from a surface of the metal layer. In some cases, the act 618 includes annealing the polycrystalline metal layer in a vacuum in an act 620. The temperature of the annealing may vary, e.g., with the composition of the metal layer. For instance, MoO₃ has a relatively low melting point (795° C.), in which case annealing above the melting point, e.g., at about 900° C., may be used. The annealing may also improve the surface roughness of the metal layer. In one example involving annealing at 900° C. for 10 minutes, except for the domain boundaries, a smooth surface was observed on each domain. Furthermore, after the high-temperature annealing, the domain boundaries were more uniform with significantly reduced misoriented clusters. The oxide may be removed in additional or alternative ways to achieve a highly ordered atomically smooth surface. For instance, the oxide may be removed via an etching procedure using, e.g., an acid solution, such as hydrochloric acid (HCl) or buffered hydrofluoric acid (BHF).

In one example, a 120-nm-thick Mo layer was grown on a Si(111) substrate. The Mo template was cleaned by acetone, methanol, and deionized water prior to loading into the MBE system used for the growth of the single-crystalline semiconductor layer. The Mo templates were then degassed at 200 and 600° C. for 2 h in the MBE load-lock chamber and preparation chamber, respectively. In the growth chamber, the Mo template was annealed at 900° C. for 10 min before starting ScAlN growth, but the temperature and other parameters may vary in other cases (e.g., in connection with the composition).

After implementing the surface treatment procedure, a non-sputtered, epitaxial growth procedure is implemented in an act 622 to form a single-crystalline semiconductor layer supported by, and in contact with, the polycrystalline metal layer. As described above, the single-crystalline semiconductor layer is composed of, or otherwise includes, an alloy of a III-nitride material. The non-sputtered, epitaxial growth procedure is configured to incorporate a group IIIB element into the alloy of the III-nitride material.

The III-nitride alloy layer may or may not be ferroelectric. As described herein, the III-nitride alloy layer has a wurtzite structure. For instance, the III-nitride material may be AIN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScAlN, for example. In some cases, the act 622 includes an act 624 in which an MBE procedure is implemented. In other cases, an MOCVD or other non-sputtered epitaxial growth procedure is implemented in an act 626.

The surface treatment of the act 618 may be implemented before (e.g., in preparation for) implementing the epitaxial growth procedure in which a wurtzite structure is formed. The wurtzite structure may thus be formed on the metal layer. The metal layer may thus act as a template for the wurtzite structure and/or other elements of the heterostructure. In some cases, the act 612 may include an act 628 in which the single-crystalline semiconductor layer is grown in a chamber in which the annealing procedure for the surface treatment of the act 618 is implemented. As a result, the substrate may remain within, e.g., is not removed from, the epitaxial growth chamber between forming the metal layer and growing the single-crystalline semiconductor layer.

The single-crystalline semiconductor layer may be grown on the metal layer using a wide growth window. For example, in some cases, the growth window may be similar to that for ScAlN grown on GaN, in which the low end of the growth temperature window is compatible with the CMOS fabrication process.

The growth temperature may be at a level such that the wurtzite structure exhibits a breakdown field strength greater than a ferroelectric coercive field strength of the wurtzite structure. Ferroelectric switching and other ferroelectric behavior may thus be achieved.

The growth temperature may be at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single-crystalline scandium-including alloy (e.g., a monocrystalline layer of the alloy) at the growth temperature level may nonetheless be achieved. For example, in some cases, a ScAlN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AIN at about 650 degrees Celsius or lower would result in structures of such poor quality. In contrast, the epitaxially grown ScAlN layer grown at that low temperature is unexpectedly of high quality and good electrical properties.

Growth of the ScAlN layer at the conventional AIN growth temperature (and other temperatures above the upper bound) unexpectedly results in the formation of dislocations and/or other leakage paths in the ScAlN layer. With the leakage paths, the ScAlN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 700 degrees Celsius, or about 750 degrees Celsius. In still other cases, the upper bound may be lower, including, for instance, about 550 degrees Celsius or about 600 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScAlN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

Additional or alternative differences in crystal quality may be used to distinguish between single-crystalline (or monocrystalline) and polycrystalline structures. As used herein, the term “polycrystalline” refers to structures having multiple domains with in-plane rotation. As used herein, the terms “monocrystalline” or “single crystalline” refer to structures having unique domains without in-plane rotation, e.g., as indicated by x-ray φ scans that have only one set of diffraction peaks.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

In some cases, the wurtzite structure of the single-crystalline semiconductor layer is metal-polar. In other cases, the single-crystalline semiconductor may be nitrogen-polar (N-polar).

In some cases, the epitaxial growth procedure is implemented under a nitrogen-rich condition. For example, the nitrogen-to-metal flux ratio may be set in an act 630 in which the nitrogen flow is controlled. In some cases, the unbalanced flux ratio may be set to a highly or extremely nitrogen (N)-rich condition, such as a N-to-metal flux ratio of 2-to-1 or higher.

Control of the flux ratio between metal and nitrogen sources may be useful for improving the material quality of the ScAlN or other III-nitride alloy layer. As described herein, the N-rich growth conditions may be useful in connection with the growth of ScAlN to avoid Sc—Al intermetallic, Sc₃AlN perovskite phase formation, and/or other defects.

In one example, ScAlN films and GaN/ScAlN heterostructures were grown utilizing a Veeco GENxplor MBE system, equipped with dual filament SUMO Knudsen cells for Al (purity 6N5) and Ga sources (purity 7N), a high-temperature Knudsen cell for Sc source (purity 5N), and a Veeco Unibulb radio frequency (RF) plasma source. The N source was operated with a N₂ gas (purity 6N) flow of 0.35 sccm, and an RF power of 350 W corresponding to a growth rate of 240 nm/h was used for metal-rich GaN layers. To maintain the single wz-phase crystal structure for ScAlN, N-rich conditions were employed. While for the GaN/ScAlN heterostructures, the GaN was grown under metal-rich conditions and slightly doped with Si (electron concentration 1×10¹⁸ cm⁻³). The thickness for ScAlN and GaN were about 100 and 20 nm, respectively. The Sc content was around 20%.

In some cases, the single-crystalline semiconductor layer may then be annealed in an act 632. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScAlN may be performed in-situ in the same growth chamber (e.g., the same MBE chamber) in an act 634. In other cases, the annealing is performed ex-situ in a chamber directed to annealing procedures.

The annealing process may be implemented under high vacuum in an act 636 (e.g., in-situ in the growth chamber). In other cases, the annealing may be implemented either with nitrogen plasma radiation or under nitrogen gas flow in an act 638.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 600 may include an act 640 in which one or more layers (e.g., semiconductor layers) are formed after growth of the wurtzite structure. As a result, the layer(s) may be in contact with the wurtzite structure. For instance, one or more III-nitride (e.g., GaN or AlGaN) or other semiconductor layers may be epitaxially grown in an act 642. The act 642 may be implemented in the same epitaxial growth chamber used to grow the wurtzite structure. As a result, the substrate (and heterostructure) is not removed from the epitaxial growth chamber between implementing the acts 622 and 640.

Alternatively or additionally, the act 640 includes an act 644 in which one or more metal or other conductive layers or structures are formed. For example, a metal layer may be deposited on the III-nitride alloy layer, in which case the III-nitride alloy layer is disposed between, and in contact with, two metal layers. The layers or structures may be deposited or otherwise formed. In some cases, the conductive structure is configured as an upper or top contact. For instance, the conductive structure may be a gate.

In some cases, the method 600 includes an act 646, in which the substrate is removed. The substrate may be partially or fully removed. With the substrate fully removed, the heterostructure becomes freestanding. In some cases, the act 646 includes implementation of an etching procedure, such as a wet or dry etch procedure. Alternatively or additionally, the substrate is removed mechanically. The manner in which the substrate is removed may thus vary accordingly.

The method 600 may include fewer, additional, or alternative acts. For example, one or more acts may be directed to forming other structures or regions of the device that includes the heterostructure. In a transistor device example, the regions may correspond with source and drain regions. The nature of the regions or structures may vary in accordance with the nature of the device. In another example, the method 600 does not include an act 610 in which a buffer layer is grown or otherwise formed.

The order of the acts of the method 600 may differ from the example shown in FIG. 6. For example, contacts and/or other structures formed in the act 610 may be implemented after the growth of the ferroelectric layer.

A number of different types of devices may be fabricated by the method 600 of FIG. 6, and/or another method of fabricating a heterostructure having a wurtzite structure of an alloy of a III-nitride material with scandium incorporated therein. For example, the ferroelectric ScAlN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

The disclosed heterostructures may be incorporated into a wide variety of devices. A number of examples are described below. The examples may or may not include a substrate supporting layers and/or structures of the heterostructure or device composed of, or otherwise include, for instance, GaN or silicon.

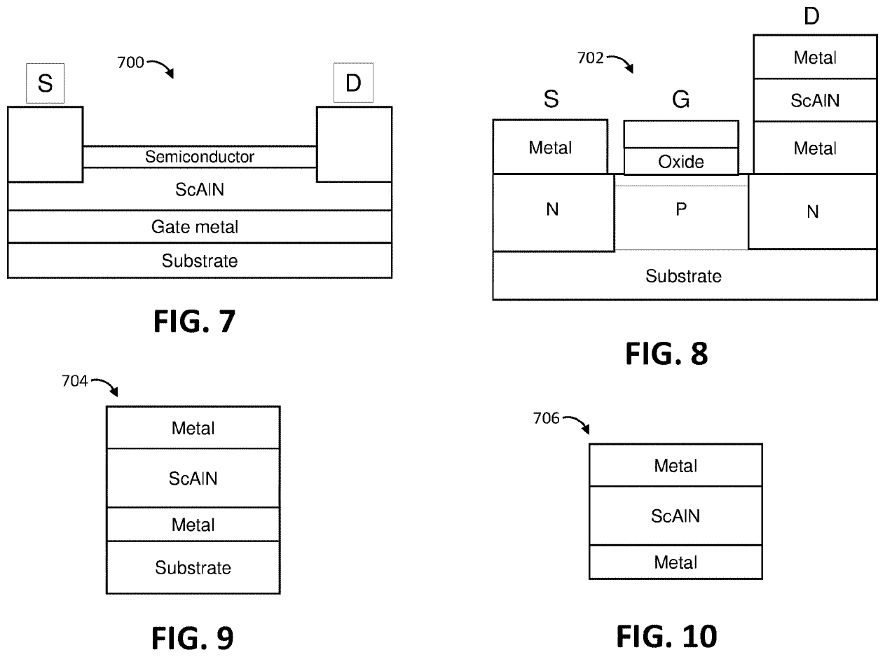

FIG. 7 depicts a FeFET memory device 700 in accordance with one example. A ferroelectric ScAlN layer is disposed between a gate electrode and a source-drain conduction region. The ferroelectric layer provides a reversible electrical state for a transistor of the device. The large remnant electrical field polarization in the ferroelectric ScAlN layer retains the state of the transistor (e.g., on or off) in the absence of any electrical bias to form a single transistor nonvolatile memory. In one example, bulk and/or other semiconductor channel layers are composed of, or otherwise include, GaN or silicon, or two-dimensional materials like MoS₂ or graphene. In each case, the FeFET memory device 700 may include a heterostructure including, for instance, the ferroelectric ScₓAl₁₋ₓN or other alloy of a III-nitride material, along with one or more layers of a III-nitride semiconductor, such as AIN, as the gate dielectric and barrier. A substrate supporting these layers and structures of the device 700 may be composed of, or otherwise include, for instance, GaN or silicon. The control terminal or gate may be disposed below the III-nitride semiconductor as shown. As described herein, the gate may be composed of, or otherwise include, a metal, such as Mo.

FIG. 8 depicts a coupled FET structure 702 configured as a memory cell in accordance with one example. During the switching of the remnant polarization state in a ScAlN layer of the FET structure 702, a current pulse is generated to indicate the stored binary information in the cell.

FIG. 9 depicts an FTJ memory device 704 in accordance with one example. In this example, an epitaxially grown ferroelectric layer of the device 704 is disposed between metal layers (e.g., nickel and aluminum layers). A ScAlN or other alloy of the ferroelectric layer provides the ferroelectricity and tunes the ON/OFF current/resistance ratio as a memorizer readout.

FIG. 10 depicts a device 706 with a heterostructure in accordance with one example. The device 706 may be configured or used as a filter, resonator, or other acoustic device. Such devices may be useful in broadband communication (e.g., 5G, 6G) contexts and other applications. In this example, the heterostructure of the device 706 is freestanding. The heterostructure may be freestanding in the sense that a growth or other sacrificial substrate has been removed. The freestanding heterostructure may be subsequently mounted on, or supported by, another structure, such as a circuit board.

In the example of FIG. 10, the heterostructure of the device 706 includes a single-crystalline III-nitride alloy layer disposed between, and in contact with, two metal layers. The composition, configuration, and other characteristics of the metal layers may vary as described herein. For instance, the metal layers may be composed of, or otherwise include, Ni, Al, Mo, or another metal. The metal layers may or may not be composed of, or include, the same metal material. In other examples, the single-crystalline III-nitride layer is in contact with only a single metal layer.

The heterostructures of the above-described devices may include any number of layers, structures, and/or components in accordance with the functionality of the device.

In other examples, a substrate other than a silicon substrate is used. For instance, the substrate may be composed of, or otherwise include, SiC or sapphire.

In other examples, the layer supported by (e.g., in contact with) the substrate is not ferroelectric.

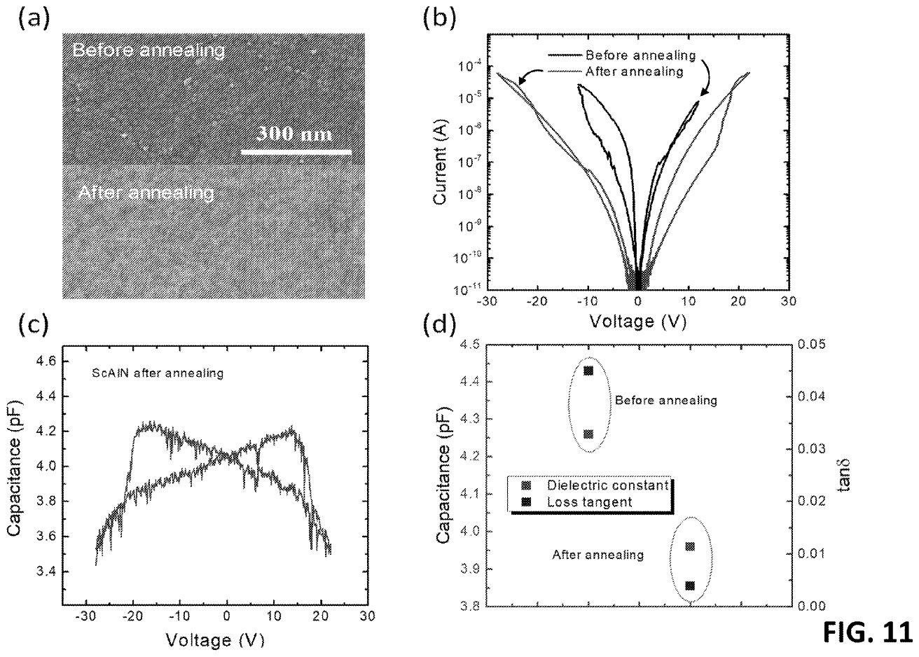

FIG. 11 provides further information regarding examples in which a ScAlN layer grown on an Mo substrate is annealed. For growth on Mo, the material quality of the ScAlN layer may be further improved by conducting in-situ annealing (e.g., at 700° C.) in the MBE chamber as described above. As shown in FIG. 11, part (a), before annealing, an example ScAlN layer grown on Mo exhibits multi-grain structure. After in-situ annealing in an MBE chamber, the surface of the ScAlN layer becomes smoother, and the multi-grains merge with one another, forming larger domains. In addition, as shown in FIG. 11, part (b), after annealing, the leakage current and breakdown voltage are also improved significantly. These improvements may enable the achievement of ferroelectric switching before breakdown in connection with ScAlN that otherwise would not be switched before breakdown, as indicated by the butterfly shape C-V loop shown in FIG. 11, part (c). Another useful result is that the dielectric constant, measured from capacitance-voltage loops, is reduced by 10% after annealing, together with an order of magnitude reduction in loss tangent, as shown in FIG. 11, part (d). Those results establish further improvements to the quality of the ScAlN films and are useful for fabricating, e.g., high-performance resonators. During annealing, the high energy domain or grain boundaries in the film may annihilate via either domain wall motion or vacancy migration, resulting in more uniform strain, composition, and impurity distribution, thereby reducing possible leakage pathways and improving the overall breakdown strength.

Described above are heterostructures that illustrate, and make use of, ferroelectricity in III-nitride (III-N) semiconductors via alloying with rare-earth elements, e.g., scandium. The ferroelectricity may be used in wide variety of electronic, acoustic, photonic, and quantum devices and systems. Rather than rely on growth of single-crystalline nitride semiconductors on sapphire, Si, or SiC substrate, which has prevented their integration with the workhorse complementary metal-oxide semiconductor (CMOS) technology, the disclosed single-crystalline ferroelectric nitride semiconductors are grown on a metal layer, e.g., a CMOS compatible metal, such as molybdenum. In examples described above, a unique epitaxial relationship between wurtzite and body-centered cubic crystal structure was perfectly maintained, enabling the realization of single-crystalline wurtzite ferroelectric nitride semiconductors on polycrystalline molybdenum that was not previously possible. Robust and wake-up-free ferroelectricity was measured, for the first time, in the epitaxially grown ScAlN on metal. Also described were example devices, including a ferroelectric GaN/ScAlN heterostructure for a synaptic memristor, which showed the capability of emulating the spike-time-dependent plasticity (STDP) in a biological synapse. The disclosed devices and methods may be useful in the integration of III-N architectures with various fabrication technologies, including, for instance, CMOS technologies, and may be useful in a number of applications, including, for instance, ferroelectric nitride memristors in neuromorphic computing.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A heterostructure comprising:
a metal layer; and
a single-crystalline semiconductor layer supported by the metal layer;
wherein:
the single-crystalline semiconductor layer comprises an alloy of a III-nitride material;
the alloy comprises a Group IIIB element; and
the single-crystalline semiconductor layer is in contact with the metal layer.

2. The heterostructure of claim 1, wherein the single-crystalline semiconductor layer is ferroelectric.

3. The heterostructure of claim 1, wherein:
the single-crystalline semiconductor layer has a wurtzite structure;
a (0001) plane of the wurtzite structure is in contact the metal layer; and
a surface of the metal layer in contact with the single-crystalline semiconductor layer matches an atomic arrangement of the (0001) plane of the wurtzite structure.

4. The heterostructure of claim 1, a surface of the metal layer is oriented in the (011) plane.

5. The heterostructure of claim 1, wherein the metal layer comprises molybdenum.

6. The heterostructure of claim 1, a surface of the metal layer is oriented in the (111) plane.

7. The heterostructure of claim 1, wherein the metal layer comprises aluminum.

8. The heterostructure of claim 1, wherein the Group IIIB element is scandium.

9. The heterostructure of claim 1, wherein the alloy of the III-nitride material comprises AIN.

10. The heterostructure of claim 1, wherein:
the metal layer is a first metal layer;
the heterostructure further comprises a second metal layer in contact with the single-crystalline semiconductor layer; and
the single-crystalline semiconductor layer is disposed between the first metal layer and the second metal layer.

11. The heterostructure of claim 1, further comprising a III-nitride semiconductor layer supported by, and in contact with, the single-crystalline semiconductor layer.

12. A device comprising the heterostructure of claim 11, wherein:
the device further comprises an electrode layer in contact with the III-nitride semiconductor layer;
the single-crystalline semiconductor layer is ferroelectric; and
the metal layer is configured as a further electrode such that the device is configured as a memristor.

13. A device comprising the heterostructure of claim 1, wherein the device further comprises a substrate, the substrate supporting the heterostructure.

14. A heterostructure comprising:
a metal layer; and
a single-crystalline semiconductor layer supported by the metal layer;
the single-crystalline semiconductor layer comprises an alloy of aluminum nitride;
the alloy comprises scandium;
the metal layer comprises molybdenum; and
the single-crystalline semiconductor layer is in contact with the metal layer.

15. The device of claim 14, wherein the single-crystalline semiconductor layer is ferroelectric.

16. The heterostructure of claim 14, wherein:
the metal layer is a first metal layer;
the heterostructure further comprises a second metal layer in contact with the single-crystalline semiconductor layer; and
the single-crystalline semiconductor layer is disposed between the first metal layer and the second metal layer.

17. A method of forming a heterostructure, the method comprising:
providing a metal layer of the heterostructure, the metal layer being supported by a substrate;
implementing a surface treatment procedure to remove oxide from a surface of the metal layer; and
after implementing the surface treatment procedure, implementing a non-sputtered, epitaxial growth procedure to form a single-crystalline semiconductor layer of the heterostructure, the single-crystalline semiconductor layer being supported by, and in contact with, the metal layer;
wherein:
the single-crystalline semiconductor layer comprises an alloy of a III-nitride material; and
the non-sputtered, epitaxial growth procedure is configured to incorporate a group IIIB element into the alloy of the III-nitride material.

18. The method of claim 17, wherein implementing the surface treatment procedure comprises annealing the metal layer in a vacuum.

19. The method of claim 17, wherein the non-sputtered, epitaxial growth procedure is implemented under a nitrogen-rich condition.

20. The method of claim 17, further comprising depositing a further metal layer on the single-crystalline semiconductor layer such that the further metal layer is in contact with the single-crystalline semiconductor layer.

21. The method of claim 17, further comprising removing the substrate such that the heterostructure is freestanding.

22. The method of claim 17, further comprising annealing the single-crystalline semiconductor layer.
